(19) United States
(12) Patent Application Publication
(10) Pub. No.: US 2025/0185452 A1
(43) Pub. Date: Jun. 5, 2025

(54) LIGHT EMITTING ELEMENT, DISPLAY DEVICE, AND NANOPARTICLE DISPERSION LIQUID

(71) Applicant: Sharp Display Technology Corporation, Kameyama City, Mie (JP)

(72) Inventors: Takayuki NAKA, Kameyama City, Mie (JP); Kazuki MARUHASHI, Kameyama City, Mie (JP); Yuki FUKUNARI, Kameyama City, Mie (JP)

(21) Appl. No.: 18/836,879

(22) PCT Filed: Mar. 30, 2023
(86) PCT No.: PCT/JP2023/013177

§ 371 Date: Aug. 8, 2024

(30) Foreign Application Priority Data
Apr. 6, 2022 (WO) PCT/JP2022/017182

(51) Int. Cl. H10K 50/115; H10K 50/15; H10K 50/17; H10K 85/30

(52) U.S. Cl. CPC H10K 50/115; H10K 50/15; H10K 50/17; H10K 85/331

(57) ABSTRACT

A light-emitting element includes an anode and a cathode, a light-emitting layer positioned between the anode and the cathode, and a charge function layer positioned between the anode and the light-emitting layer and including a nanoparticle including a metal atom, in which the charge function layer includes an organic molecule including a first functional group capable of bonding to the nanoparticle, a second functional group having a hole transport property, and a hydrocarbon group having 1 to 4 carbon atoms.

### TECHNICAL FIELD

The disclosure relates to a light-emitting element and the like.

### BACKGROUND ART

PTL 1 discloses a light-emitting element including nickel oxide nanoparticles between electrodes.

### CITATION LIST

### Patent Literature

PTL 1: US 2021/0091325 A1

### SUMMARY

### Technical Problem

Known light-emitting elements have a problem of high drive voltage.

### Solution to Problem

A light-emitting element according to the disclosure includes: an anode and a cathode; a light-emitting layer positioned between the anode and the cathode; and a charge function layer positioned between the anode and the light-emitting layer and including a nanoparticle including a metal atom, in which the charge function layer includes an organic molecule having a first functional group capable of bonding to the nanoparticle, a second functional group having a hole transport property, and a hydrocarbon group having 1 to 4 carbon atoms.

### Advantageous Effects of Disclosure

The drive voltage of the light-emitting element can be reduced.

### BRIEF DESCRIPTION OF DRAWINGS

FIG. 1 is a cross-sectional view illustrating a configuration example of a light-emitting element according to the present embodiment.

FIG. 2 is a cross-sectional view illustrating a configuration example of a light-emitting element according to a first embodiment.

FIG. 3 is a cross-sectional view illustrating a configuration example of a light-emitting element according to a second embodiment.

FIG. 4 is a cross-sectional view illustrating a configuration example of the light-emitting element according to the second embodiment.

FIG. 5 is a cross-sectional view illustrating a configuration example of a light-emitting element according to a third embodiment.

FIG. 6 is a cross-sectional view illustrating a configuration example of the light-emitting element according to the third embodiment.

FIG. 7 is a flowchart showing a method for manufacturing a nanoparticle according to Example 1.

FIG. 8 is a flowchart showing a method for manufacturing a nanoparticle dispersion liquid according to Example 1.

FIG. 9 is a flowchart showing a method for manufacturing a light-emitting element according to Example 1.

FIG. 10 is a graph showing a V-L characteristic (voltage-luminance characteristic) of each light-emitting element.

FIG. 11 is a graph showing a J-L characteristic (current-luminance characteristic) of each light-emitting element.

FIG. 12 is a graph showing a P-L characteristic (power consumption-luminance characteristic) of each light-emitting element.

FIG. 13 is a schematic diagram illustrating a configuration example of an organic molecule.

FIG. 14 is a structural formula showing a specific example of an organic molecule.

FIG. 15 is a flowchart showing a method for manufacturing a nanoparticle dispersion liquid of Example 3.

FIG. 16 is a schematic diagram illustrating the nanoparticle dispersion liquid of Example 3.

FIG. 17 is a structural formula showing a specific example of a first organic additive.

FIG. 18 is a graph showing V-L characteristics (power consumption-luminance characteristics) of light-emitting elements A and B.

FIG. 19 is a graph showing J-L characteristics (power consumption-luminance characteristics) of the light-emitting elements A and B.

FIG. 20 is a graph showing P-L characteristics (power consumption-luminance characteristics) of the light-emitting elements A and B.

FIG. 21 is a graph showing external quantum effects (EQE) of the light-emitting elements A and B.

FIG. 22 is a schematic diagram illustrating a configuration example of a display device according to the present embodiment.

### DESCRIPTION OF EMBODIMENTS

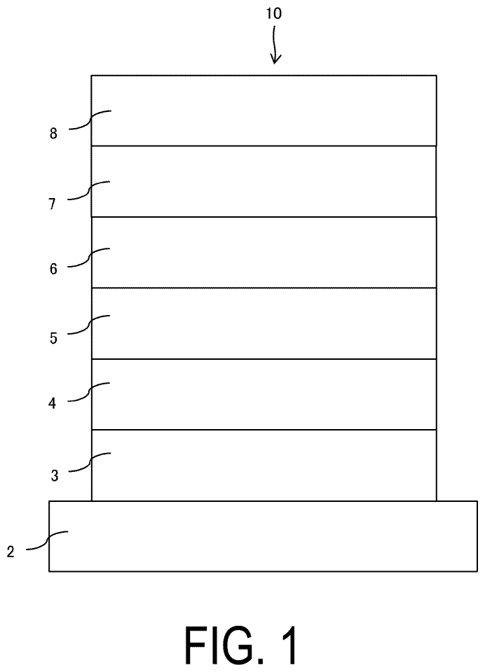

FIG. 1 is a cross-sectional view illustrating a configuration example of the light-emitting element according to the present embodiment. A light-emitting element 10 may have a structure in which an anode 3, a charge function layer 4, a hole transport layer 5, a light-emitting layer 6, an electron transport layer 7, and a cathode 8 are layered in this order from the lower side to the upper side. The charge function layer 4 has, for example, a hole injection function. The anode 3 may be formed on a substrate 2 (e.g., a TFT substrate).

The anode 3 supplies holes to the light-emitting layer 6. The cathode 8 supplies electrons to the light-emitting layer 6. The cathode 8 may be positioned so as to face the anode 3. In FIG. 1, the cathode 8 is positioned above the anode 3.

At least one of the anode 3 and the cathode 8 may be formed of a light-transmissive material. A transparent conductive material can be used as the light-transmissive material, for example. As the transparent conductive material, for example, indium tin oxide (ITO), indium zinc oxide (IZO), tin oxide (SnO₂), fluorine-doped tin oxide (FTO), or the like can be used. Since these materials have high transmittance of visible light, the luminous efficiency of the light-emitting element 1 is improved.

At least one of the anode 3 and the cathode 8 may be formed of a light-reflective material. A metal material can be used as the light-reflective material, for example. As the metal material, for example, aluminum (Al), silver (Ag), copper (Cu), gold (Au), or the like can be used. Since these materials have high reflectance of visible light, the luminous efficiency of the light-emitting element 1 is improved.

The charge function layer 4 may be positioned between the anode 3 and the light-emitting layer 6. In the example of FIG. 1, the charge function layer 4 is positioned between the anode 3 and the hole transport layer 5. The charge function layer 4 injects a hole from the anode 3 into the light-emitting layer 6.

The hole transport layer 5 may include an organic material. In the example of FIG. 1, the hole transport layer 5 is positioned between the charge function layer 4 and the light-emitting layer 6. When the hole transport layer 5 is included, the luminous efficiency of the light-emitting element 10 can be improved.

The light-emitting layer 6 may be positioned between the anode 3 and the cathode 8. In the example of FIG. 1, the light-emitting layer 6 is positioned between the hole transport layer 5 and the electron transport layer 7. The light-emitting layer 6 may include any light-emitting material that emits light by recombination of a hole supplied from the anode 3 and an electron transported from the cathode 8. The light-emitting element 10 may be configured to emit light in the light-emitting layer 6 by applying a voltage or a current between the anode 3 and the cathode 8.

As an example, the light-emitting layer 6 may include quantum dots as a light-emitting material. The quantum dot means a dot (particle) having a maximum width of 100 nm or less. The shape of the quantum dot is not particularly limited as long as it is within a range satisfying the maximum width, and the shape is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination thereof. The quantum dot is typically a semiconductor single crystal, and may have a particle size of 1.0 nm to 50 nm. The quantum dot may have a crystal of a group II-VI semiconductor compound such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, or HgTe, and/or a group III-V semiconductor compound such as GaAs, GaP, InN, InAs, InP, or InSb, and/or a group IV semiconductor compound such as Si or Ge. The quantum dot may have, for example, a core-shell structure in which the above-described semiconductor crystal is used as a core and the core is overcoated with a shell material having a high band gap. The light-emitting layer 6 may include a ligand that adsorbs (coordinates) to a quantum dot surface. The ligand may be an organic ligand or an inorganic ligand including, for example, a halogen. The light-emitting layer 6 may have a configuration including an inorganic continuous film (e.g., a metal sulfide film such as ZnS) including a quantum dot group.

In FIG. 1, the electron transport layer 7 is positioned between the light-emitting layer 6 and the cathode 8. The electron transport layer 7 transports electrons from the cathode 8 to the light-emitting layer 6. The electron transport layer 7 includes an electron transport material. Examples of the electron transport material include compounds or complexes including one or more nitrogen-including hetero rings such as an oxadiazole ring, a triazole ring, a triazine ring, a quinoline ring, a phenanthroline ring, a pyrimidine ring, a pyridine ring, an imidazole ring, and carbazole ring.

Further examples of the electron transport material include 1,10-phenanthroline derivatives such as bathocuproine and bathophenanthroline, benzimidazole derivatives such as 1,3,5-tris (N-phenylbenzimidazole-2-yl)benzene (TPBI), bis(10-benzoquinolinolato) beryllium complexes, 8-hydroxyquinoline Al complexes, metal complexes such as bis (2-methyl-8-quinolinate)-4 phenylphenolate aluminum, and 4,4′-biscarbazole biphenyl. Other examples include aromatic boron compounds, aromatic silane compounds, aromatic phosphine compounds such as phenyldi (1-pyrenyl) phosphine, and nitrogen-containing heterocyclic compounds such as bathophenanthroline, bathocuproine, and triazine derivatives.

Other examples of the electron transport material include zinc oxide (ZnO), zinc magnesium oxide (MgZnO), titanium oxide (TiO₂), and strontium oxide (SrTiO₃). These materials may be nanoparticles. As described above, the electron transport layer 7 may include MgZnO. In this case, the injection of electrons is suppressed, the carrier balance of the light-emitting element 10 is easily adjusted, and the luminous efficiency is improved.

The nanoparticles are particles having a maximum width of 1000 nm or less. The shape of the nanoparticle is not particularly limited as long as it is within a range satisfying the maximum width, and the shape is not limited to a spherical three-dimensional shape (circular cross-sectional shape). The shape of the quantum dot may be, for example, a polygonal cross-sectional shape, a rod-shaped three-dimensional shape, a branch-shaped three-dimensional shape, or a three-dimensional shape having unevenness on the surface thereof, or a combination thereof. Typically, it is a semiconductor particle, and the particle size may be 1.0 nm to 50 nm. The nanoparticle may be a single crystal or a polycrystal.

### First Embodiment

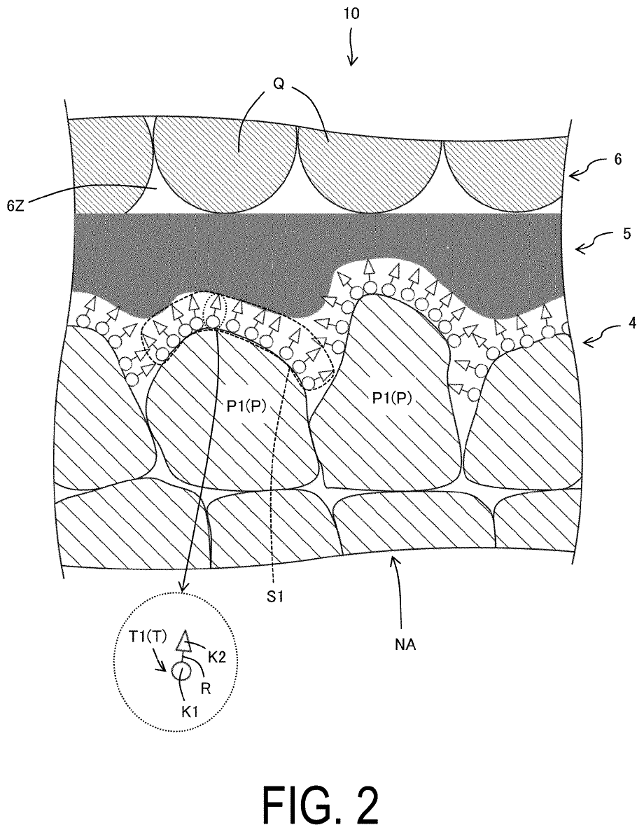

FIG. 2 is a cross-sectional view illustrating a configuration example of the light-emitting element according to the first embodiment. As illustrated in FIGS. 1 and 2, the light-emitting element 10 includes a first nanoparticle P1 positioned between the anode 3 and the light-emitting layer 6 and including a metal atom, and an organic molecule T1 having a first functional group K1 capable of bonding to the first nanoparticle P1 and a second functional group K2 having a hole transport property, the organic molecule T1 being positioned between the light-emitting layer 6 and the first nanoparticle P1. The organic molecule T1 has a hydrocarbon group R having 1 to 4 carbon atoms. Since the organic molecule T1 can be densely adsorbed to the surface of the first nanoparticle P1 by the hydrocarbon group R, the hydrocarbon group R has an effect of improving the hole transport property of the charge function layer 4, thereby decreasing the drive voltage of the light-emitting element 10.

The organic molecule T1 may be a single molecule that can autonomously exist on the surface of the first nanoparticle P1. Since the organic molecule T1 has the first functional group K1 capable of bonding to the first nanoparticle P1, a first molecular assembly S1 including a plurality of the organic molecules T1 may be positioned along the surface of the first nanoparticle P1.

The first molecular assembly S1 may be a self-assembled monolayer (SAM) having a self-assembly ability. This is because the first molecular assembly S1 (self-assembled monolayer) can be formed by a simple method (described later) such as applying the anode 3 with a solution in which the organic molecule T1 is dissolved in a solvent.

In the first molecular assembly S1, a plurality of the same organic molecules T1 are preferably arranged adjacent to each other. This is because the film thickness can be uniformized by defining the thickness by the organic molecules T1, the film quality can also be uniformized by including the same organic molecules T1, and since the same organic molecules T1 are adjacent to each other, the organic molecules T1 can be densely distributed in a film. Furthermore, it is preferable that the plurality of organic molecules T1 constituting the first molecular assembly S1 be arranged at equal distances between adjacent molecules because they can be distributed more densely. It is preferable that the plurality of organic molecules T1 constituting the first molecular assembly S1 be arranged in the same orientation as one another because the organic molecules T1 can be more densely distributed, and a stronger bond can be formed by interaction.

In the first embodiment, the charge function layer 4 includes a nanoparticle group NA, and the molecular assembly S1 is formed in the first nanoparticle P1 positioned on the surface of the nanoparticle group NA. Since a large number of the organic molecules T1 belonging to the molecular assembly S1 have the first functional group K1 that bonds (e.g., chemically bonds) to the first nanoparticle P1, they are arranged along the surface of the first nanoparticle P1, which is a particle. A surface defect (e.g., a hole trap) of the first nanoparticle P1 is reduced by the organic molecule T1. Since the organic molecule T1 has the second functional group K2 having a hole transport property, a hole path from the charge function layer 4 to the hole transport layer 5 increases, and the drive voltage of the light-emitting element 10 decreases. The light-emitting layer 6 may include a light-emitting quantum dot Q. The light-emitting layer 6 may have a configuration including an inorganic matrix material (e.g., a metal sulfide film such as ZnS) 6Z filling a space between a plurality of quantum dots Q including an inorganic semiconductor.

The first nanoparticle P1 may be composed of an inorganic compound having a hole transport property including a metal atom. For example, the first nanoparticle P1 may include at least one of Ni, Cu, Cr, Ta, Mo, tungsten (W), Re, and vanadium (V). The first nanoparticles P1 may include a metal oxide. As an example, the metal oxide may be nickel oxide (NiO). When the first nanoparticle P1 includes a metal oxide, the stability of bonding with the organic molecule T1 can be improved.

### Second Embodiment

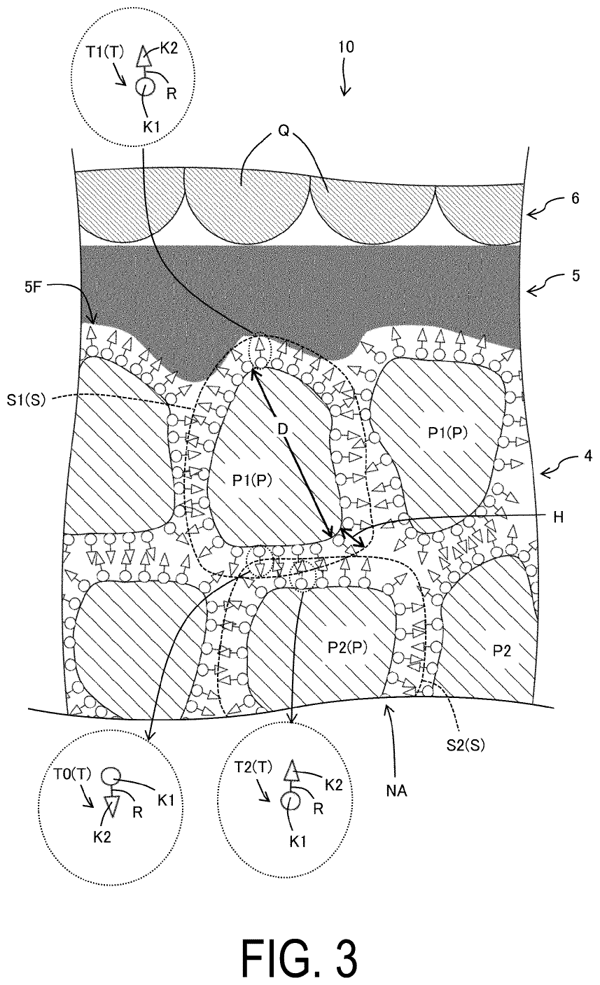

FIG. 3 is a cross-sectional view illustrating a configuration example of the light-emitting element according to the second embodiment. As illustrated in FIGS. 1 and 3, the light-emitting element 10 includes the first nanoparticle P1 and a second nanoparticle P2 positioned between the anode 3 and the light-emitting layer 6 and including a metal atom, and an organic molecule TO having the first functional group K1 capable of bonding to the first nanoparticle P1 and the second functional group K2 having a hole transport property, the organic molecule TO being positioned between the first nanoparticle P1 and the second nanoparticle P2. The organic molecule TO may be a single molecule that can autonomously exist on the surface of the first nanoparticle P1.

The light-emitting element 10 may include another organic molecule T1 having the first functional group K1 capable of bonding to the first nanoparticle P1 and the second functional group K2 having a hole transport property, the other organic molecule T1 being positioned between the light-emitting layer 6 and the first nanoparticle P1. The organic molecule T1 may be a single molecule that can autonomously exist on the surface of the first nanoparticle P1.

The light-emitting layer 6 may include the light-emitting quantum dot Q, and the quantum dot Q may be a core-shell type. Note that the light-emitting layer 6 may be a thin organic film (e.g., vapor deposition film).

The first molecular assembly S1 including a plurality of the organic molecules T0 and T1 may be positioned along the surface of the first nanoparticle P1. The first molecular assembly S1 may be positioned around the first nanoparticles P1.

The light-emitting element 10 may include a second molecular assembly S2 including an organic molecule T2 having a first functional group capable of bonding to the second nanoparticle P2 and a second functional group having a hole transport property, and the second molecular assembly S2 may be positioned around the second nanoparticle P2. Each of the plurality of organic molecules T2 included in the second molecular assembly S2 may be a single molecule that can autonomously exist on the surface of the second nanoparticle P2. As illustrated in FIG. 3, the first nanoparticle P1 may be close to the light-emitting layer 6 relative to the second nanoparticle P2.

A part of the first molecular assembly S1 and a part of the second molecular assembly S2 may be in contact with each other. Each of the first and second nanoparticles P1 and P2 may be a non-sphere. A thickness H of the first molecular assembly S1 may be smaller than a particle size D of the first nanoparticle. The first molecular assembly S1 (including the plurality of organic molecules T0 and T1) may be adsorbed to the surface of the first nanoparticle P1. The organic molecules T0, T1, and T2 may have an identical molecular structure or different molecular structures.

The organic hole transport layer 5 may be positioned between the first nanoparticle P1 and the light-emitting layer 6. The organic hole transport layer 5 may include an organic material having the second functional group K2. The charge function layer 4 may include the nanoparticle group NA including the first nanoparticle P1, and a lower surface 5F of the organic hole transport layer 5 may have a shape along the surface unevenness of the nanoparticle group NA. The organic hole transport layer 5 may be a flattening film, and the surface unevenness of the nanoparticle group NA may be flattened by the organic hole transport layer 5.

In the second embodiment, the charge function layer 4 includes the nanoparticle group NA, the molecular assembly S1 is formed in the first nanoparticle P1, the molecular assembly S2 is formed in the second nanoparticle P2 adjacent to the first nanoparticle P1, and the large number of organic molecules T0, T1, and T2 belonging to the first and second molecular assemblies S1 and S2 have the second functional group K2 having a hole transport property. Therefore, in the light-emitting element 10, the hole path from the charge function layer 4 to the hole transport layer 5 increases, a barrier between nanoparticles is reduced, and the drive voltage of the light-emitting element 10 can be reduced.

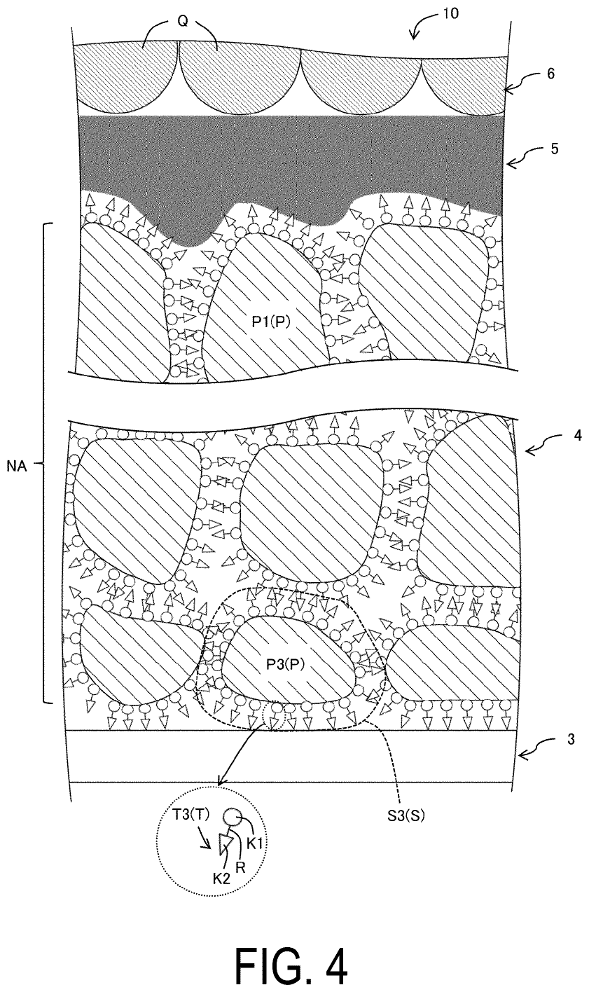

FIG. 4 is a cross-sectional view illustrating a configuration example of the light-emitting element according to the second embodiment. As illustrated in FIG. 4, the light-emitting element 10 may include a third molecular assembly S3 including a third nanoparticle P3 adjacent to the anode 3 and an organic molecule T3 having the first functional group capable of bonding to the third nanoparticle P3 and the second functional group having a hole transport property, and the third molecular assembly S3 may be positioned around the third nanoparticle P3 and may be in contact with the anode 3. The organic molecule T3 may be a single molecule that can autonomously exist on the surface of the third nanoparticle P3. Due to this, the hole path from the anode 3 to the nanoparticle group NA (having a hole transport property) increases, and the drive voltage of the light-emitting element 10 can be reduced.

When the particle size of the nanoparticle P (generic term for P1 and P2) is too small (e.g., when the particle size is less than 4.0 nm), the hole transport function of the nanoparticle P itself can be lowered. On the other hand, when the particle size of the nanoparticle P is too large (e.g., when the particle size exceeds 100 nm), the number of voids in the charge function layer 4 increases, and the hole transport property can be lowered. From this, the particle size distribution of the first nanoparticles P1 may be 4.0 to 100 [nm]. Therefore, for example, a D50 mean particle size of the first nanoparticles P1 may be 5.0 to 40 [nm].

In the light-emitting element 10, the self-assembled monolayer (SAM) may be configured by the molecular assembly S (generic term for S1 and S2). Note that although the molecular assembly S is illustrated by a broken line including the nanoparticle P and the organic molecule T, the molecular assembly S means an assembly part of the organic molecule T excluding the nanoparticle P. The organic molecule T (generic term for TO, T1, and T2) can be bonded to the nanoparticle Pas an inorganic hole transport material. However, when the size of the organic molecule T is too small (e.g., when the thickness of the self-assembled monolayer is less than 0.5 nm), the bonding of the organic molecule T to the inorganic hole transport material can be weak. On the other hand, when the size of the organic molecule T is too large (e.g., when the thickness of the self-assembled monolayer exceeds 1.5 nm), the hole transport property between the nanoparticles P can be lowered. From this, the thickness of the self-assembled monolayer may be 0.5 to 1.5 [nm]. Note that there may be a space in which the organic molecule T does not exist between the nanoparticles.

In the nanoparticle group NA of the charge function layer 4, an inter-particle mean distance may be 2.5 [nm] or less. In this case, hole transport between the nanoparticles P is smoothed.

The number of functional groups capable of bonding to the nanoparticle P included in the organic molecule T may be 2 or less including the first functional group K1. In this case, it is possible to prevent the hole transport from being inhibited by the functional group unbonded to the nanoparticle P.

The first functional group K1 may include at least one functional group selected from a carboxyl group, a silanol group, a phosphoryl group (e.g., a phosphono group), a thiol group, and an amino group. In this case, bonding between the first functional group and the nanoparticle P easily occurs.

The second functional group K2 may include at least one functional group selected from a carbazole group, a tetracyano group, a triarylamine group, a fluorene group, a quinonediimide group, a phthalocyanine group, a triphenylene group, and a phenylnaphthalene group. Among them, a carbazole group, a triarylamine group, and a fluorene group are preferably included, and the organic molecule T can exhibit a high hole transport property.

The organic molecule T has the hydrocarbon group R having 1 to 4 carbon atoms. Since the organic molecule T can be densely adsorbed to the surface of the nanoparticle P by the hydrocarbon group R, the hydrocarbon group R has an effect of suppressing aggregation of the nanoparticle P and improving the hole transport property of the charge function layer 4, thereby decreasing the drive voltage of the light-emitting element 10. The hydrocarbon group R may be an alkyl group. The organic molecule T can be densely adsorbed to the surface of the nanoparticle P by the alkyl group. The alkyl group may have 2 or less carbon atoms. In this case, the organic molecule T can be densely adsorbed to the surface of the nanoparticle P, and the distance between the second functional group K2 and the nanoparticle P is shortened, and the hole transport property can be improved.

### Third Embodiment

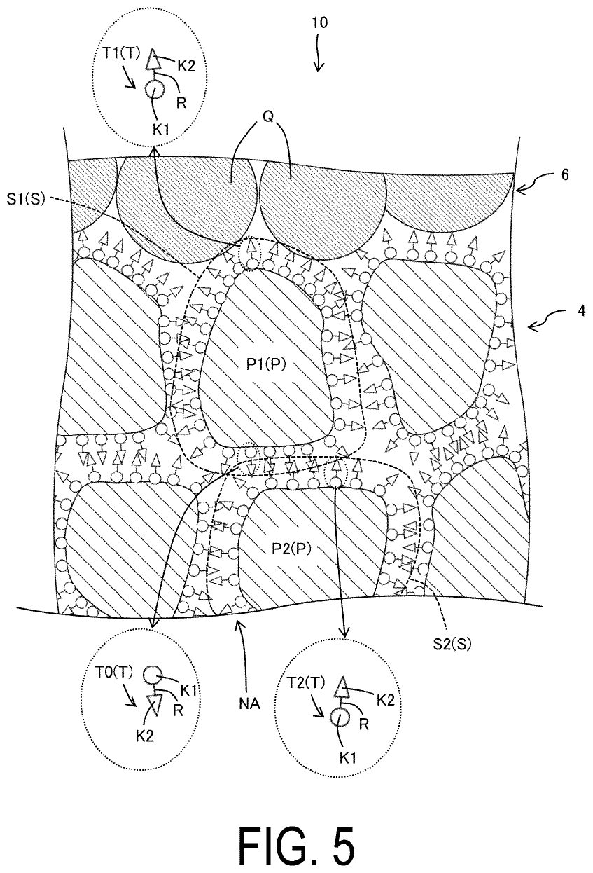

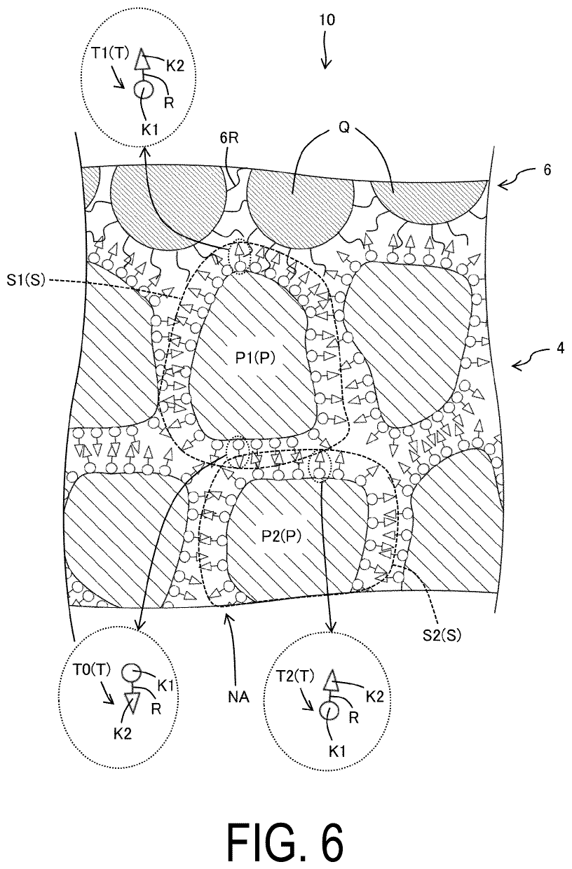

FIGS. 5 and 6 are cross-sectional views illustrating a configuration example of the light-emitting element according to the third embodiment. As illustrated in FIG. 5, the light-emitting layer 6 may be configured to include a plurality of the light-emitting quantum dots Q, a charge function layer 4 may be configured to include the nanoparticle group NA, and the first molecular assembly S1 formed on the first nanoparticle P1 on the surface of the nanoparticle group NA may be in contact with the quantum dots Q. The organic molecule T1 constituting the first molecular assembly S1 has the hydrocarbon group R having 1 to 4 carbon atoms. Since the organic molecule T can be densely adsorbed to the surface of the nanoparticle P by the hydrocarbon group R, the hydrocarbon group R has an effect of suppressing aggregation of the nanoparticle P and improving the hole transport property of the charge function layer 4, thereby decreasing the drive voltage of the light-emitting element 10.

The charge function layer 4 may have a hole transport function. As illustrated in FIG. 6, the first molecular assembly S1 may be in contact with a ligand 6R positioned around the quantum dot Q. The ligand 6R in FIG. 6 may be an organic ligand or an inorganic ligand such as a halogen.

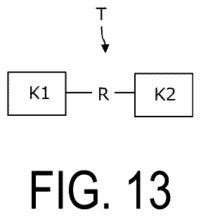

FIG. 13 is a schematic diagram illustrating a configuration example of an organic molecule. As illustrated in FIG. 13, the organic molecule T of the charge function layer 4 may include the first functional group K1 capable of bonding to the nanoparticle P, the second functional group K2 having a hole transport property, and the hydrocarbon group R having 1 to 4 carbon atoms. The organic molecule T may include the first functional group K1 capable of bonding to the nanoparticle P, the second functional group K2 including at least one of a carbazole group, a tetracyano group, a triarylamine group, a fluorene group, a quinone diimide group, a phthalocyanine group, a triphenylene group, and a phenylnaphthalene group, and the hydrocarbon group R having 1 to 4 carbon atoms. The organic molecule T can be densely adsorbed to the surface of the nanoparticle P by the hydrocarbon group R, and aggregation suppression of the nanoparticle P and improvement of the hole transport property can be achieved.

The first functional group K1 may include at least one of a carboxyl group, a silanol group, a phosphono group, a thiol group, and an amino group. The hydrocarbon group R may be a linking group that links the first functional group K1 and the second functional group K2. The organic molecule T may be a self-assembled single molecule. A self-assembled single molecule group (self-assembled monolayer) including an organic molecule may surround the nanoparticle P.

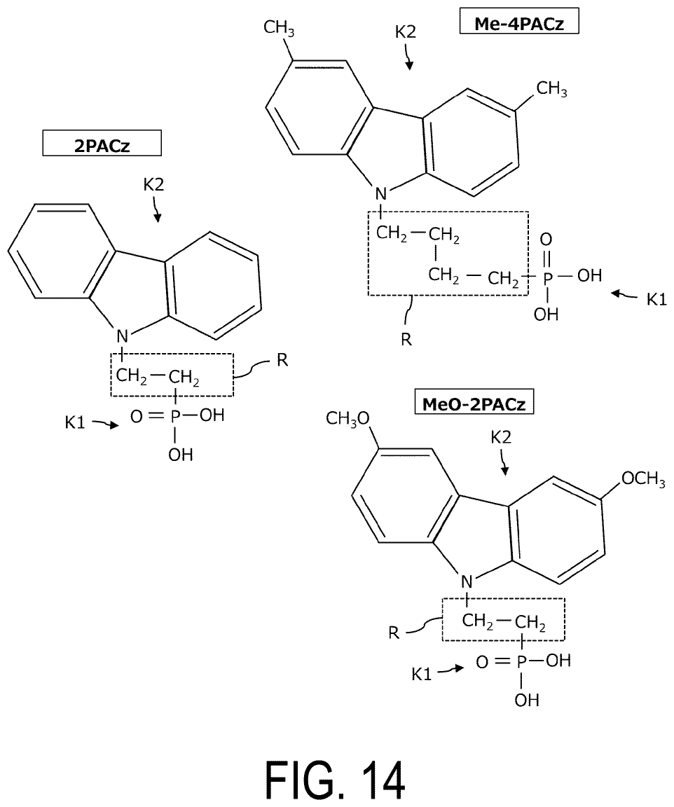

FIG. 14 is a structural formula showing a specific example of an organic molecule. As illustrated in FIGS. 13 and 14, the hydrocarbon group R may be an alkyl group. The organic molecule T can be densely adsorbed to the surface of the nanoparticle P by the alkyl group. The alkyl group may have 2 or less carbon atoms. In this case, the organic molecule T can be densely adsorbed to the surface of the nanoparticle P, and the distance between the second functional group K2 and the nanoparticle P is shortened, and the hole transport property can be improved.

The hydrocarbon group R may be bonded to a phosphorus atom included in the first functional group K1. The metal atom included in the nanoparticle P may be nickel, and the molar ratio of phosphorus to nickel may be 0.1 or less. The hydrocarbon group R may be bonded to a nitrogen atom included in the second functional group K2. The nanoparticle P may include nickel oxide. The first functional group K1 may include a phosphoryl group. The second functional group K2 may include a carbazole group.

The organic molecule T may be any of 2PACz, Me-2PACz, MeO-2PACz, and Me-4PACz. The organic material included in the (organic) hole transport layer 5 may have the second functional group K2. 2PACz is also referred to as [2-(9H-carbazol-9-yl)ethyl] phosphonic acid. MeO-2PACz is also referred to as [2-(3,6-dimethoxy-9H-carbazole-9-yl)ethyl] phosphonic acid. Me-4PACz is also referred to as [4-(3,6-dimethyl-9H-carbazole-9-yl)butyl] phosphonic acid.

### Example 1

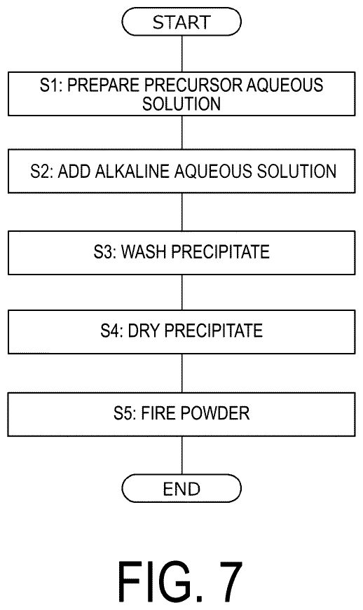

FIG. 7 is a flowchart showing a method for manufacturing a nanoparticle according to Example 1. In S1, a precursor aqueous solution is prepared. In Example 1, 0.05 mmol of nickel nitrate hexahydrate (Ni(NO₃)₂·6H₂O) and 20 mL of pure water were mixed and stirred to prepare the precursor aqueous solution.

In S2, an alkaline aqueous solution is added to the precursor aqueous solution obtained in S1. In Example 1, a 10 mol/L aqueous sodium hydroxide solution was added to the precursor aqueous solution until the pH reached 9 to 11 (e.g., pH 10). As a result of S2, a precipitate (e.g., green precipitate) is obtained.

In S3, the precipitate obtained as a result of S2 is washed. In Example 1, a washing process of adding pure water to the green precipitate, centrifuging the mixture, and then removing the supernatant was repeated three times.

In S4, the precipitate after washing is dried. In Example 1, the green precipitate after washing was dried at 60 to 100° C. (e.g., 80° C.). As a result of S4, powder (e.g., green powder) is obtained.

In S5, the powder obtained as a result of S4 is fired. In Example 1, green powder was fired at 250 to 300° C. for 2 to 6 hours (e.g., 270° C. for 2 hours). As a result, black nickel oxide nanoparticle powder is obtained. The nickel oxide nanoparticle prepared as described above has a nitrate ion and has high dispersibility to water.

An example of a method for evaluating the nanoparticle manufactured by the manufacturing method of FIG. 7 will be described. In the method for evaluating, measurement of the particle size of the nanoparticle and measurement of the crystallite diameter of the nanoparticle are performed.

First, the flow of processing for measuring the particle size of the nanoparticle will be exemplified. First, the nanoparticle is dispersed in an aqueous solvent and passed through a filter (e.g., filter having a pore size of 0.45 μm) to prepare a solution. Subsequently, the solution is subjected to particle size distribution measurement using a particle size distribution measurement device (e.g., Nanotrac wave II, manufactured by MicrotracBEL). The particle size of the nanoparticle is determined from the result obtained by the particle size distribution measurement. Subsequently, a median diameter D50 (nm) of the nanoparticle is determined from the result obtained by particle size distribution measurement. In the present description, D50 is also referred to as the mean particle size. As a result of measuring the particle size of the nickel oxide nanoparticle manufactured in Example 1, the particle size was 5.4 to 61 nm, and D50 was 9.4 nm.

Subsequently, the flow of processing for measuring the crystallite diameter of the nanoparticle will be exemplified. First, X-ray intensity with respect to a diffraction angle 2θ is measured for the nanoparticle using a powder X-ray diffraction (XRD) device (e.g., MiniFlex II, manufactured by Rigaku Corporation).

A crystallite diameter d (nm) of the nanoparticle is determined in accordance with the Scherrer equation given below

d=0.89λ/(B cos θ) . . . (1). In the equation (1), 2 (nm) is a wavelength of an X-ray. As an example, a Cu Kα ray with λ=0.154 nm may be used. B is a full width at half maximum (FWHM) of the X-ray diffraction peak. As a result of measuring the crystallite diameter d of the nickel oxide nanoparticle manufactured in Example 1, d=4.1 nm.

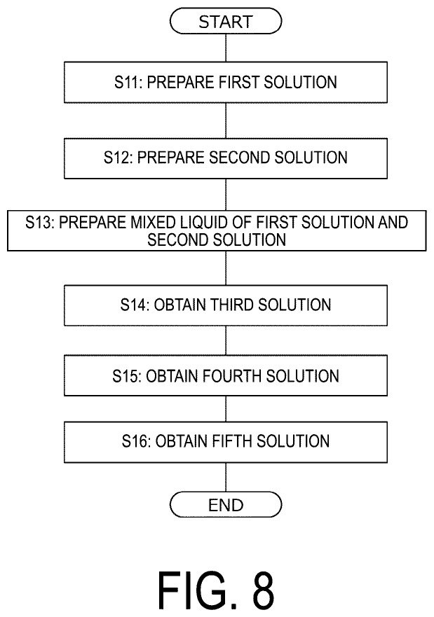

FIG. 8 is a flowchart showing a method for manufacturing a nanoparticle dispersion liquid according to Example 1. The method for manufacturing may include (i) preparing a mixed liquid of a first solution obtained by dispersing, in a first solvent, a plurality of nanoparticles including a metal compound and a second solution obtained by dispersing an organic molecule in a second solvent; (ii) stirring a third solution obtained by adding a first organic additive to the mixed liquid; and (iii) obtaining a fourth solution by separating, from a first solvent part, a second solvent part in the third solution after stirring.

As is apparent from each description above, in the method for manufacturing, the organic molecular material may have the first functional group having affinity for a metal compound and the second functional group having a hole transport property.

In S11, the first solution is prepared by dispersing the plurality of nanoparticles in the first solvent. The first solvent may be pure water. In Example 1, 10 mg of nickel oxide nanoparticles were dispersed in 1 mL of pure water to prepare an aqueous dispersion of nanoparticles as the first solution.

In S12, the organic molecules are dispersed in the second solvent to prepare the second solution. The second solvent may be pure water. In Example 1, 0.02 mmol of MeO-2PACz was dispersed in 1 mL of pure water to prepare an aqueous dispersion of organic molecules as the second solution.

In S13, a mixed liquid of the first solution obtained in S11 and the second solution obtained in S12 is prepared. S13 may include stirring the mixed liquid.

In S14, the third solution is obtained by adding the first organic additive to the mixed liquid obtained in S13. Then, the obtained third solution is stirred. The first organic additive may have a ketone group. In Example 1, the third solution was obtained by adding, to the mixed liquid obtained in S13, 2 mL of methyl ethyl ketone as an organic solvent having a ketone group.

In S15, the fourth solution is obtained by separating, from the first solvent part, the second solvent part in the third solution after stirring.

For example, the second solvent part and the first solvent part in the third solution after stirring may be an upper layer and a lower layer, respectively, of the third solution after stirring. In this case, the second solvent part, which is the upper layer, mainly includes a nanoparticle and an organic solvent. On the other hand, the first solvent part, which is the lower layer, does not mainly include a nanoparticle but mainly includes water. Then, the fourth solution can be obtained by taking out the upper layer from the third solution after stirring, for example. Alternatively, the fourth solution can be obtained by removing the lower layer from the third solution after stirring.

S15 may include subjecting the fourth solution to ultrasonication. The ultrasonication can enhance dispersibility of the nanoparticles in the fourth solution.

In S16, a fifth solution is obtained by adding the second organic additive to the fourth solution subjected to the ultrasonication in S15. Then, the nanoparticle dispersion liquid is obtained by subjecting the fifth solution to filtering.

In Example 1, the fifth solution was obtained by adding 1.2 ml of propylene glycol monomethyl ether acetate (PGMEA) to the fourth solution subjected to the ultrasonication. Then, the nickel oxide nanoparticle dispersion liquid was obtained by passing the fifth solution through a filter having a pore size of 0.2 μm.

An example of a method for evaluating the nanoparticle dispersion liquid manufactured by the manufacturing method of FIG. 8 will be described. In the method for evaluating, measurement of the particle size of the nanoparticle included in the nanoparticle dispersion liquid and measurement of the crystallite diameter of the nanoparticle are performed.

First, particle size distribution measurement of the nanoparticles included in the nanoparticle dispersion liquid is performed using the above-described particle size distribution measurement device. Then, as described above, the particle size and D50 of the nanoparticle are determined. As a result of measuring the particle size of the nickel oxide nanoparticle included in the nickel oxide nanoparticle dispersion liquid manufactured in Example 1, the particle size was 9.0 to 50 nm, and D50 was 15.1 nm.

The powder obtained by heating the nanoparticle dispersion liquid is subjected to X-ray intensity measurement using an XRD device as described above. Then, the crystallite diameter d is determined using the above-described equation (1). As a result of measuring the crystallite diameter d of the nickel oxide nanoparticle included in the nickel oxide nanoparticle dispersion liquid manufactured in Example 1, d=4.1 nm.

When the crystallite diameter d is too small (e.g., when d is less than 3.8 nm), the conductivity of the nanoparticles can be lowered. On the other hand, when the crystallite diameter d is too large (e.g., when d exceeds 15 nm), the number of voids in an inorganic layer increases, and the hole transport property in the inorganic layer can be lowered. Thus, the crystallite diameter d may be 3.8 to 15 nm.

As a reference example, a mixed liquid was obtained by mixing 10 mg of nickel oxide nanoparticles, 0.02 mmol of MeO-2PACz, and 2 mL of methyl ethyl ketone without performing S11 and S12. In this case, precipitation occurred after the mixed liquid was stirred, and a good nanoparticle dispersion liquid could not be obtained. As another reference example, in S14, an organic solvent having no ketone group (e.g., ethanol, ethyl acetate, diethylene glycol diethyl ether, or the like) was used. Also, in this case, precipitation occurred, and a good nanoparticle dispersion liquid could not be obtained.

As is apparent from each description above, the nanoparticle dispersion liquid of Example 1 may contain (i) a plurality of nanoparticles including a metal compound, (ii) a first organic additive including a ketone group, and a plurality of organic molecules each having a first functional group having affinity for the metal compound and a second functional group having a hole transport property. In this case, the nanoparticle has good dispersibility to an organic solvent by bonding the organic molecule to the surface of the nanoparticle.

For example, the nanoparticle dispersion liquid according to Example 1 may contain (i) a plurality of nanoparticles including a metal compound, (ii) a first organic additive including a ketone group, and a plurality of organic molecules each including at least one selected from a carboxyl group, a silanol group, a phosphono group, a thiol group, and an amino group, and at least one selected from a carbazole group, a tetracyano group, a triarylamine group, a fluorene group, a quinonediimide group, a phthalocyanine group, a triphenylene group, and a phenylnaphthalene group. The organic molecule has a hydrocarbon group having 1 to 4 carbon atoms. Since the organic molecule can be densely adsorbed to the surface of the nanoparticle by the hydrocarbon group, the hydrocarbon group has an effect of suppressing aggregation of the nanoparticle in the nanoparticle dispersion liquid, and has an effect of improving the hole transport property of the charge function layer as a light-emitting element. The hydrocarbon group R may be an alkyl group. The organic molecule can be densely adsorbed to the surface of the nanoparticle by the alkyl group. The alkyl group may have 2 or less carbon atoms. In this case, the organic molecule can be densely adsorbed to the surface of the nanoparticle, and the distance between the second functional group and the nanoparticle is shortened, and the hole transport property can be improved. This decreases the drive voltage of the light-emitting element. The organic molecule may be at least one selected from MeO-2PACz, 2PACz, and Me-4PACz.

In the nanoparticle dispersion liquid according to Example 1, when the particle size of the nanoparticle is too small (e.g., less than 4.0 nm), the aggregation property of the nanoparticles becomes strong, and the stability of dispersion of the nanoparticles can be lowered. On the other hand, when the particle size of the nanoparticle is too large (e.g., when the particle size exceeds 100 nm), the dispersibility of the nanoparticle is lowered, and there is a high possibility that precipitation is likely to occur. Therefore, the particle size distribution of the plurality of nanoparticles may be 4.0 to 100 [nm]. D50 of the plurality of nanoparticles may be 5.0 to 40 [nm].

In the nanoparticle dispersion liquid according to Example 1, the thickness of the self-assembled monolayer including a plurality of organic molecules may be 0.5 to 1.5 [nm].

In the nanoparticle dispersion liquid according to Example 1, each nanoparticle may include a nitrate ion. In this case, since MeO-2PACz can be bonded to the surface of the nanoparticle with high density, the nanoparticle has good dispersibility to the organic solvent.

The solubility of the first organic additive to water may be 250 to 500 g/L (20° C.). Also, in this case, the nanoparticle has good dispersibility to the organic solvent.

The boiling point of the first organic additive may be 100° C. or more and 300° C. or less. In this case, it is possible to prevent an unevenness due to rapid volatilization of the organic solvent from occurring at the time of forming the above-described inorganic layer. In addition, it is possible to prevent the organic molecule from being destroyed by heat at the time of heating for volatilizing the organic solvent. More preferably, the boiling point of the first organic additive may be 140° C. or more and 200° C. or less.

The nanoparticle dispersion liquid according to an aspect of the disclosure may contain the second organic additive that is miscible with water and has viscosity. In this case, the inorganic layer can be uniformly formed on a conductive substrate. However, when the concentration of the second organic additive is too low (e.g., when the concentration is less than 5 vol % with respect to the entire dispersion liquid), the uniformity of the inorganic layer can be lowered. On the other hand, when the concentration of the second organic additive is too high (e.g., when the concentration exceeds 50 vol % with respect to the entire dispersion liquid), the dispersibility of the nanoparticle to the organic solvent can be lowered. Therefore, the concentration of the second organic additive may be 5 to 50 vol % with respect to the entire dispersion liquid.

The viscosity of the second organic additive may be 7.5 mPa·s (20° C.) or more. In this case, a thick inorganic layer can be easily manufactured. As the viscosity of the second organic additive increases, a thicker inorganic layer can be easily manufactured. Therefore, for example, the viscosity may be preferably 20 mPa·s (20° C.) or more, and more preferably 50 mPa·s (20° C.) or more.

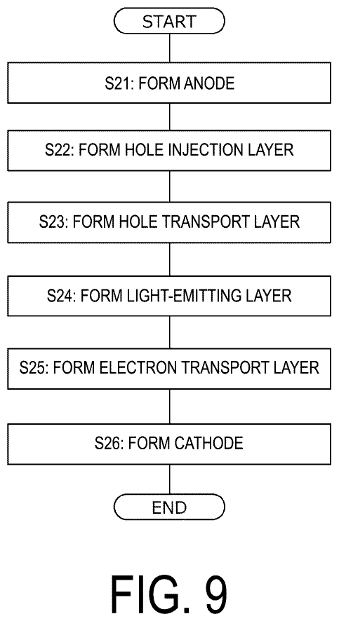

FIG. 9 is a flowchart showing the method for manufacturing the light-emitting element according to Example 1. The method for manufacturing may include: (i) forming an anode; and (ii) applying the nanoparticle dispersion liquid obtained by the method for manufacturing a nanoparticle dispersion liquid according to an aspect of the disclosure onto the anode using spin coating or an inkjet method.

In S21, the anode is formed. In Example 1, an ITO film having a film thickness of 30 nm and 2 mm×10 mm was formed as an anode by sputtering ITO as an anode material on a substrate (not illustrated).

In S22, the charge function layer 4 is formed. In Example 1, 0.1 ml of the nickel oxide nanoparticle dispersion liquid is applied by spin coating onto the anode formed in S21. Then, the charge function layer 4 was formed by drying the dispersion liquid at 150° C. In Example 1, an inorganic layer having a film thickness of 20 nm (thin film of the dispersion liquid) was formed as the charge function layer 4.

Note that when the inkjet method is used as the method for applying the nanoparticle dispersion liquid in S22, the mass productivity of the nanoparticle dispersion liquid light-emitting element can be enhanced.

In S23, the hole transport layer is formed. In Example 1, a solution in which 8 mg of p-TPD was dissolved in 1 ml of chlorobenzene was applied by spin coating onto the charge function layer 4 formed in S22 to form a hole transport layer (more specifically, an organic hole transport layer) having a film thickness of 40 nm.

In S24, the light-emitting layer is formed. In the third embodiment, 0.05 ml of a QD solution including InP/ZnS (core/shell) was applied by spin coating onto the hole transport layer formed in S23 to form a light-emitting layer having a film thickness of 15 nm.

In S25, the electron transport layer is formed. In Example 1, MgZnO having a particle size of 5 nm was applied by spin coating onto the light-emitting layer formed in S24 to form an electron transport layer having a film thickness of 60 nm.

In S26, the cathode is formed. In Example 1, Ag as a cathode material was vacuum-deposited on the electron transport layer formed in S25 to form an Ag electrode having a thickness of 50 nm as a cathode.

### Comparative Example

As a comparative example, instead of the above-described S22, S22R described below was performed to manufacture a light-emitting element. This comparative example is positioned as a comparison target of Example 1, and is included in the present embodiment.

In S22R, an aqueous dispersion of nickel oxide nanoparticles is spin-coated onto the anode (ITO). Then, the aqueous dispersion is dried at 200° C. to form a thin film of nickel oxide nanoparticles. 0.01 M of a solution in which MeO-2PACz is dissolved in ethanol is prepared. The solution is brought into contact with the thin film of nickel oxide nanoparticles for 5 seconds or more, and then an inorganic layer as a hole injection layer is formed by drying treatment.

A method for evaluating the light-emitting element is as follows. Each light-emitting element (Example 1 and Comparative Example 1) was evaluated using a luminance/spectrum measurement device (MCPD 7000 manufactured by Otsuka Electronics Co., Ltd.) and a current-voltage characteristic measurement device (manufactured by Keithley, 2400). First, a voltage V (voltage between a cathode and an anode) was applied to each light-emitting element so that a current J (more precisely, current density) was included in a range of 0 mA/cm² to 30 mA/cm².

Then, a luminance value L of the light emitted from each light-emitting element along with the application of the voltage of V was measured using the luminance/spectrum measurement device. Specifically, V was variously changed, and L corresponding to each V was measured. V was variously changed, and J corresponding to each V was measured using the current-voltage characteristic measurement device.

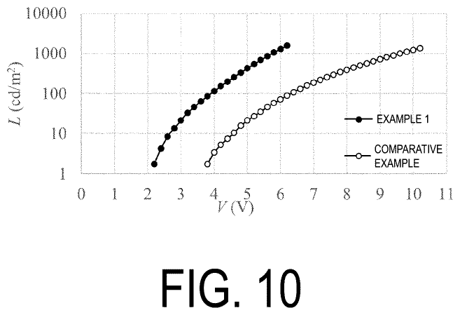

FIG. 10 is a graph showing a V-L characteristic (voltage-luminance characteristic) of each light-emitting element. As shown in FIG. 10, the V-L characteristic is improved in Example 1 as compared with that in the comparative example. Specifically, in the present embodiment, a threshold voltage is reduced by about 1.6 V as compared with that in the comparative example. The threshold voltage in the example of FIG. 10 is the minimum value of the voltage at which L becomes 1 cd/m² or more. The threshold voltage can also be paraphrased as a voltage at which light emission of the light-emitting element is started.

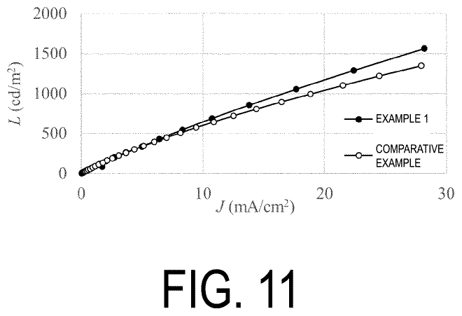

FIG. 11 is a graph showing a J-L characteristic (current-luminance characteristic) of each light-emitting element. In Example 1, the J-L characteristic is also improved as compared with that in the comparative example.

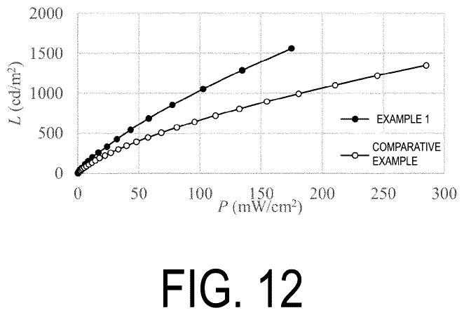

FIG. 12 is a graph showing a P-L characteristic (power consumption-luminance characteristic) of each light-emitting element. P in the example of FIG. 12 is calculated as J×V. In Example 1, the P-L characteristic is also improved as compared with that in the comparative example. Specifically, in Example 1, power consumption for achieving a predetermined luminance is reduced as compared with that in the comparative example.

The light-emitting element 10 according to Example 1 includes (i) the plurality of nanoparticles P, and (ii) the plurality of organic molecules T having the first functional group K1 capable of bonding to the nanoparticles P and the second functional group K2 having a hole transport property. As an example, the charge function layer 4 of the present embodiment includes nickel oxide nanoparticles as the nanoparticles P. The charge function layer 4 of the present embodiment includes the organic molecules T between the nickel oxide nanoparticles.

The inventors of the present application presume factors for effect development in Example 1 as follows. According to Example 1, existence of defects (the defect inhibits hole injection) on the surface of the nanoparticles P can be reduced. Specifically, since the organic molecule has the first functional group capable of bonding to the nanoparticle, the organic molecule can be adsorbed to the surface of the nanoparticle. Therefore, the surface defect of the nanoparticle can be compensated by the organic molecule. For example, —PO₄H₂ as the first functional group can be bonded to Ni²⁺ of nickel oxide (NiO).

According to Example 1, since the organic molecule has the second functional group having a hole transport property, hole transport between adjacent nanoparticles can be smoothed. As a result, a barrier between nanoparticles can be reduced.

According to the above factors, the voltage required for hole transport in the charge function layer 4 can be reduced, and the efficiency of hole injection can be improved. As a result, it is presumed that in Example 1, excellent characteristics are achieved as compared with those in the comparative example.

It is known that the P-L characteristic can be improved in a light-emitting element by disposing an organic molecule on the surface of NiO. Therefore, Example 1 can have an excellent P-L characteristic as compared with that of a light-emitting element in which no organic molecule is disposed on the surface of NiO.

Factors for improvement of the P-L characteristic are presumed to be, for example, (i) compensation of the surface defect of NiO by organic molecules, and (ii) smoothing of hole transport from the charge function layer 4 to the hole transport layer 5 or the light-emitting layer 6. Improvement in adhesion between the charge function layer 4 and the hole transport layer 5 or the light-emitting layer 6 is also presumed as a further factor.

Here, it is considered an organic molecule having (i) the first functional group chemically bondable to a nanoparticle as an inorganic hole transport material and (ii) the second functional group having a hole transport property. In general, since the size of an organic molecule is about 1.5 nm or less, it is considered that not a little polarization (dipole) occurs in the organic molecule having the first functional group and the second functional group. As a further factor for improvement of the P-L characteristic, it is also considered that (i) the difference in an energy level (VBM) between the charge function layer 4 and the hole transport layer 5 or the light-emitting layer 6 was reduced due to this polarization.

As shown in FIG. 10, the V-L characteristic is improved in Example 1 as compared with that in the comparative example. From this, it is inferred that in Example 1, an unexpected effect development factor acts at the present time point. As described above, the effect of Example 1 is a specific effect that cannot be easily assumed by those skilled in the art according to the common general technical knowledge at the present time point.

As described above, when the particle size of the nanoparticle is too small (e.g., when the particle size is less than 4.0 nm), the conductivity of the nanoparticles can be lowered. When D is too small (e.g., when D is less than 3.8 nm), the conductivity of the nanoparticles can be lowered. It is also presumed that the problem assumed as described above, which is that “a barrier or a trap occurs in hole transport in the charge function layer 4”, becomes apparent when the conductivity of the nanoparticles is lowered. Also from this point, it is considered that the particle size distribution of the nanoparticles is preferably 4.0 to 100 [nm]. Similarly, it is considered that the crystallite diameter d is preferably 3.8 to 15 nm.

### Method for Identifying Charge Function Layer

Here, an example of a method for identifying the charge function layer 4 will be described. Regarding the nanoparticle as an inorganic hole transport material, the particle size is obtained by observing at least 50 particles in a cross section of the light-emitting element with transmission electron microscopy (TEM) or, as the next method, with scanning electron microscopy (SEM) to calculate a mean value of individual particle sizes. Specifically, the diameter of a circle having the same area as the area occupied by the particle is defined as the particle size of the particle. Furthermore, by combining TEM and energy dispersive X-ray spectroscopy (EDX) or, as the next method, by combining SEM and EDX, elemental analysis is performed on the cross section of the light-emitting element, whereby the material can be identified. The crystallite diameter is calculated by measuring the size of an interference fringe of a crystal in an observation image by TEM of a cross section of the light-emitting element. Specifically, for at least 10, preferably 50 or more, interference fringes, a longest part in a direction perpendicular to the interference fringe in one interference fringe is measured, and the mean value thereof is obtained. Note that the light-emitting element may be measured by in-plane XRD, and the crystallite diameter may be calculated using the Scherrer equation for the peak of the obtained spectrum. Here, the cross section of the light-emitting element is obtained by focused ion beam (FIB) processing.

Next, the organic molecule can be identified by performing etching up to the charge function layer 4 by gas cluster ion beam (GCIB), and by analysis using time-of-flight secondary ion mass spectrometry (TOF-SIMS) of the charge function layer 4 and tandem mass spectrometry (MS/MS).

### Example 2

In Example 2, 4-methoxy-4-methyl-2-pentanone was used as the organic solvent having a ketone group in S14. In Example 2, propylene glycol was used as the second organic additive in S16. Specifically, the fifth solution was obtained by adding 0.65 ml of propylene glycol to the fourth solution.

As a result of measuring the particle size of the nickel oxide nanoparticle included in the nickel oxide nanoparticle dispersion liquid manufactured in Example 2, the particle size was 9.0 to 86 nm, and D50 was 16.2 nm. The crystallite diameter d was 4.2 nm.

In Example 2, in S22, 0.1 ml of the nickel oxide nanoparticle dispersion liquid was applied onto the anode (ITO) by spin coating. Then, the charge function layer 4 was formed by drying the dispersion liquid at 200° C. Specifically, it was formed as the charge function layer 4 having a film thickness of 33 nm. In Example 2, the thick charge function layer 4 is formed. The charge function layer 4 in Example 2 is formed as a nanoparticle thin film having higher uniformity and less unevenness.

In Example 2, since S23 is skipped, as illustrated in FIG. 5, the first molecular assembly S1 including the organic molecules T1 is in contact with the quantum dot Q of the light-emitting layer 6. It was confirmed that the P-L characteristic was also improved in Example 2. That is, in Example 2, power consumption for achieving a predetermined luminance is reduced as compared with that in the comparative example.

The charge function layer 4 of Example 2 includes the nickel oxide nanoparticles as nanoparticles, and includes the organic molecule between the nickel oxide nanoparticles. Therefore, in Example 2, it is presumed that an excellent P-L characteristic is achieved by the similar mechanism to that in Example 1.

### Example 3

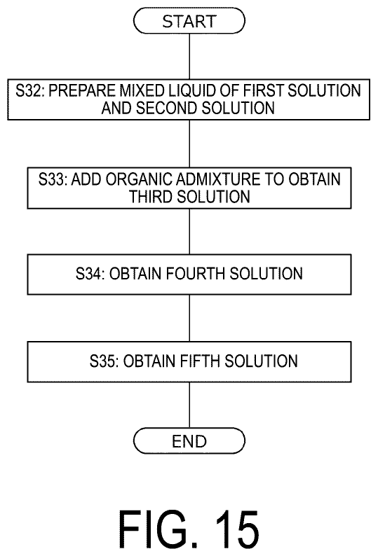

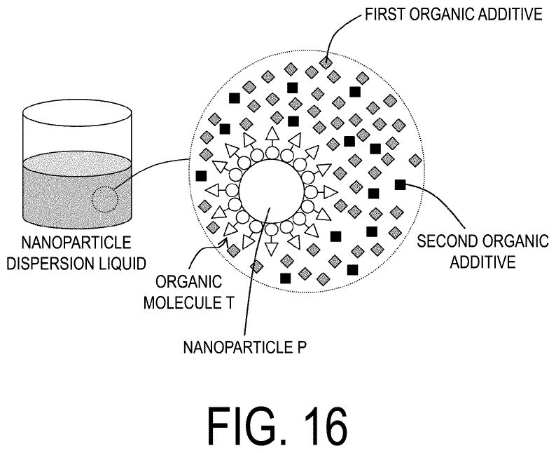

FIG. 15 is a flowchart showing a method for manufacturing a nanoparticle dispersion liquid of Example 3. FIG. 16 is a schematic diagram illustrating the nanoparticle dispersion liquid of Example 3. As shown in FIGS. 15 and 16, Example 3 includes S32 of preparing a mixed liquid of a first solution including a nanoparticle containing a metal compound and a first solvent and a second solution including an organic molecular material and a second solvent, S33 of adding an organic admixture to this mixed liquid to obtain a third solution, S34 of adding a first organic additive (e.g., including a carbonyl group) to a precipitate obtained from the third solution (e.g., taken out by a centrifugal separation method) to obtain a fourth solution, and S35 of adding a second organic additive to the fourth solution to obtain a fifth solution. S34 may include subjecting the fourth solution to ultrasonication. The ultrasonication can enhance dispersibility of the nanoparticles in the fourth solution. The nanoparticle dispersion liquid of FIG. 16 is obtained by subjecting the fifth solution to filtering.

The second organic additive may be greater in viscosity at 20° C. than the first organic additive. The first organic additive may include a carbonyl group and an ether group. The boiling point of the first organic additive may be higher than the boiling point of the second organic additive. The boiling point of the first organic additive may be 210° C. or more.

Since the boiling point of the first organic additive is higher than the boiling point of the second organic additive, dispersibility of nanoparticles is easily maintained after film formation, that is, after application and drying, a flat film is formed, and a stable light emission characteristic as a light-emitting element can be obtained.

The first solvent and the second solvent may be pure water. The solubility of the first organic additive to water may be 250 to 500 g/L (20° C.).

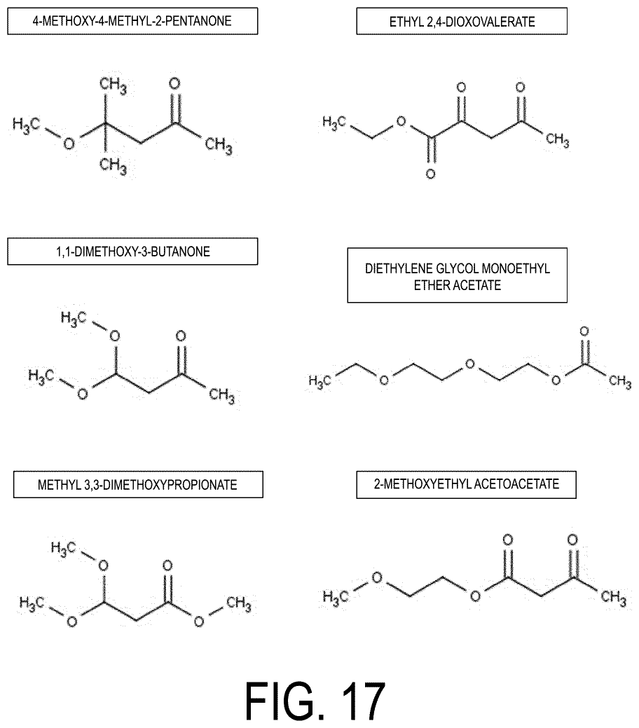

FIG. 17 is a structural formula showing a specific example of the first organic additive. The first organic additive may include at least one of 4-methoxy-4-methyl-2-pentanone (boiling point: 156° C.), 1,1-dimethoxy-3-butanone (boiling point: 170° C.), methyl 3,3-Dimethoxypropionate (boiling point: 179° C.), ethyl 2,4-Dioxovalerate (boiling point: 215° C.), diethylene glycol monoethyl ether acetate (boiling point: 218° C.), and 2-methoxyethyl acetoacetate (boiling point: 229° C.). As the boiling point of the first organic additive (dispersion solvent) is higher (e.g., 150° C. or more), a stable and flat film is formed by inkjet film formation, and a stable light emission characteristic as a light-emitting element can be obtained.

Here, the first organic additive includes a plurality of carbonyl groups or includes a carbonyl group and an ether group, whereby the boiling point of the first organic additive becomes high. Due to this, a stable and flat film is formed by inkjet film formation, and a stable light emission characteristic as a light-emitting element can be obtained.

Examples of the organic admixture in S33 include a material miscible with an equal amount (same volume) of pure water among materials that can be used as the first organic additive. In this way, a precipitate can be generated in S33. Different materials may be used for the organic admixture and the first organic additive, or the same material may be used for the organic admixture and the first organic additive.

As the organic admixture, 1,1-dimethoxy-3-butanone, methyl 3,3-dimethoxypropionate, diethylene glycol monoethyl ether acetate, or 2-methoxyethyl acetoacetate can be used.

The second organic additive may include propylene glycol (boiling point: 187[° C.], viscosity 56 [mPa·s]), dipropylene glycol, ethylene glycol (boiling point: 197 [° C.], viscosity 20 [mPa·s]), diethylene glycol (boiling point: 244[° C.], viscosity 32 [mPa·s]), and at least one of 1,3-propanediol (boiling point: 213[° C.], viscosity 52 [mPa·s]), 1,3-butanediol, and 2,3-butanediol. The viscosity (20° C.) of the second organic additive may be 18 [mPa·s] or more, 28 [mPa·s] or more, or 48 [mPa·s] or more. This improves the wettability to the electrode (e.g., anode).

Use of at least one of ethyl 2,4-dioxovalerate, diethylene glycol monoethyl ether acetate, and 2-methoxyethyl acetoacetate as the first organic additive and use of propylene glycol as the second organic additive make it easier to maintain dispersibility of nanoparticles after film formation (application and drying).

The nanoparticle dispersion liquid generated in FIGS. 8 and 15 can also be used as an inkjet solution. For example, the charge function layer 4 can be formed by applying a nanoparticle dispersion liquid onto an electrode (e.g., anode) using an inkjet method.

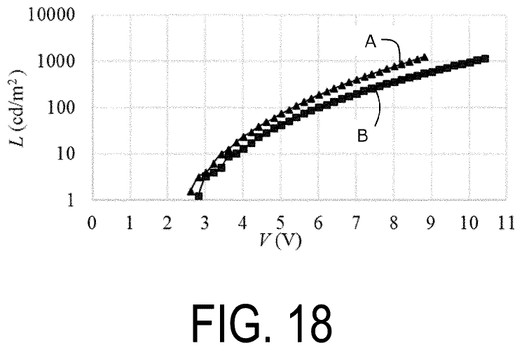

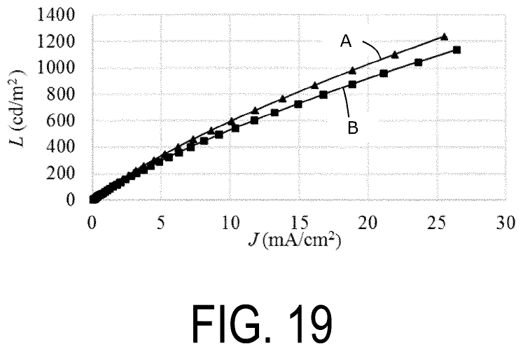

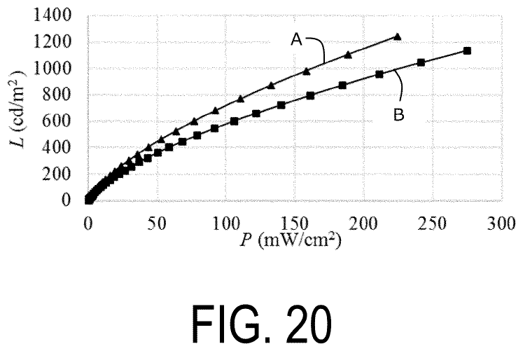

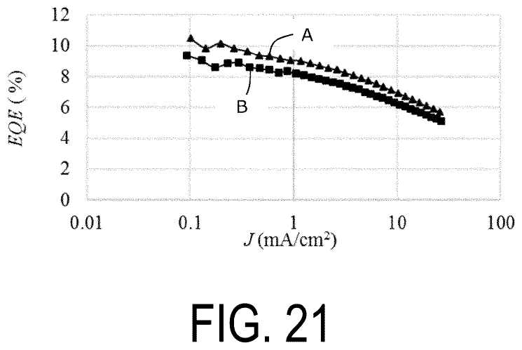

FIG. 18 shows voltage-luminance characteristics of the light-emitting element A using the method for manufacturing of FIG. 15 and the light-emitting element B using the method for manufacturing of FIG. 8. FIG. 19 shows current density-luminance characteristics of the light-emitting element A using the method for manufacturing of FIG. 15 and the light-emitting element B using the method for manufacturing of FIG. 8. FIG. 20 shows power density-luminance characteristics of the light-emitting element A using the method for manufacturing of FIG. 15 and the light-emitting element B using the method for manufacturing of FIG. 8. FIG. 21 shows current density-external quantum effects (EQE) of the light-emitting element A using the method for manufacturing of FIG. 15 and the light-emitting element B using the method for manufacturing of FIG. 8.

The manufacture of the light-emitting element A uses 1,1-dimethoxy-3-butanone as an organic admixture, 4-methoxy-4-methyl-2-pentanone as the first organic additive, and propylene glycol monomethyl ether (PGME) as the second organic additive. The manufacture of the light-emitting element B uses 4-methoxy-4-methyl-2 pentanone as the first organic additive and propylene glycol monomethyl ether (PGME) as the second organic additive.

FIGS. 18 to 20 indicate that the light-emitting element A has lower voltage, lower current, and lower power than those of the light-emitting element B. FIG. 21 indicates that the light-emitting element A is higher in EQE than the light-emitting element B. It is presumed that this is because organic molecules not adsorbed to nanoparticles in the nanoparticle dispersion liquid were reduced by the use of the method for manufacturing of FIG. 15 (precipitate is made the fourth solution by centrifugation). Note that analysis of the light-emitting element A finds that the molar ratio of the nanoparticles (nickel oxide) and the organic molecules (molar ratio of the phosphorus element P to the nickel element Ni) was 0.1 or less. For this analysis, X-ray photoelectron spectroscopy was used. That is, by setting the molar ratio of the nanoparticles (nickel oxide) to the organic molecules (molar ratio of the phosphorus element P to the nickel element Ni) to 0.1 or less, it is possible to further enhance the EQE with low voltage, low current, and low power of the light-emitting elements.

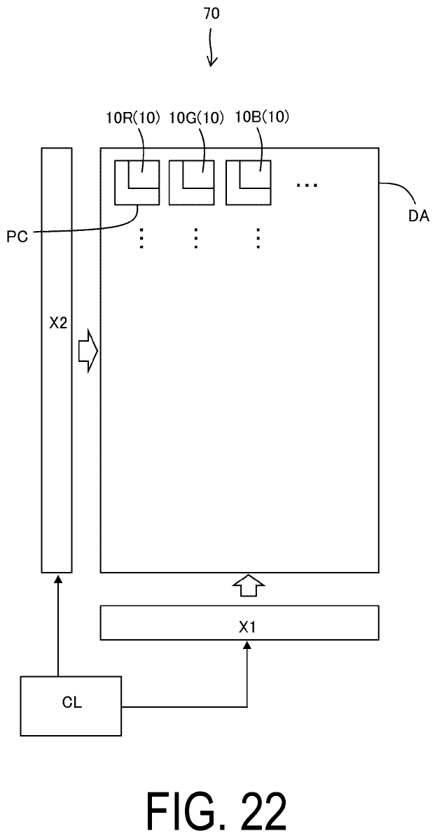

FIG. 22 is a schematic diagram illustrating a configuration example of a display device according to the present embodiment. A display device 70 includes a display unit DA, a first driver circuit X1 (e.g., a data signal line drive circuit) and a second driver circuit X2 (e.g., a scanning signal line drive circuit and a light emission control line drive circuit) that drive the display unit DA, and a control circuit CL that controls the first driver circuit X1 and the second driver circuit X2. The display unit DA may include a pixel circuit layer and a light-emitting element layer. The light-emitting element layer may include a light-emitting element 10R (10) that emits red light, a light-emitting element 10G (10) that emits green light, and a light-emitting element 10B (10) that emits blue light, and each of the light-emitting elements 10R, 10G, and 10B may be connected to a pixel circuit PC formed in the pixel circuit layer.

### APPENDIX

The embodiments described above are for the purpose of illustration and description and are not intended to be limiting. It will be apparent to those skilled in the art that many variations will be possible in accordance with these examples and descriptions.

1. A light-emitting element comprising:
an anode and a cathode;
a light-emitting layer positioned between the anode and the cathode; and
a charge function layer positioned between the anode and the light-emitting layer and including a nanoparticle including a metal atom,
wherein the charge function layer includes an organic molecule having a first functional group capable of bonding to the nanoparticle, a second functional group having a hole transport property, and a hydrocarbon group.

2. A light-emitting element comprising:
an anode and a cathode;
a light-emitting layer positioned between the anode and the cathode; and
a charge function layer positioned between the anode and the light-emitting layer and including a nanoparticle including a metal atom,
wherein the charge function layer includes an organic molecule having a first functional group including at least one of a carboxyl group, a silanol group, a phosphoryl group, a thiol group, and an amino group, a second functional group including at least one of a carbazole group, a tetracyano group, a triarylamine group, a fluorene group, a quinone diimide group, a phthalocyanine group, a triphenylene group, and a phenylnaphthalene group, and a hydrocarbon group having 1 to 4 carbon atoms.

3. The light-emitting element according to claim 1,
wherein the hydrocarbon group is a linking group that links the first functional group and the second functional group.

4. The light-emitting element according to claim 1,
wherein the hydrocarbon group is an alkyl group.

5. The light-emitting element according to claim 4,
wherein the alkyl group has 2 or less carbon atoms.

6. (canceled)

7. (canceled)

8. The light-emitting element according to claim 1,
wherein the organic molecule is a self-assembled single molecule.

9. The light-emitting element according to claim 8,
wherein a self-assembled single molecule group including the organic molecule surrounds the nanoparticle.

10. The light-emitting element according to claim 1,
wherein the nanoparticle includes nickel oxide.

11. The light-emitting element according to claim 1,
wherein the hydrocarbon group is bonded to a phosphorus atom included in the first functional group, and
the first functional group includes a phosphoryl group.

12. The light-emitting element according to claim 1,
wherein the hydrocarbon group is bonded to a nitrogen atom included in the second functional group, and
the second functional group includes a carbazole group.

13. The light-emitting element according to claim 1,
wherein the hydrocarbon group is bonded to a phosphorus atom included in the first functional group,
the metal atom is nickel, and
a molar ratio of phosphorus to nickel is 0.1 or less.

14. The light-emitting element according to claim 1,
wherein the organic molecule is any of MeO-2PACz, 2PACz, and Me-4PACz.

15. The light-emitting element according to claim 1,
wherein the charge function layer has a hole injection function, and
a hole transport layer is provided between the charge function layer and the light-emitting layer, the hole transport layer including an organic material having the second functional group.

16. The light-emitting element according to claim 1,
wherein the light-emitting layer includes a plurality of quantum dots including an inorganic semiconductor, and an inorganic matrix material filling a space between the plurality of quantum dots.

17. A display device comprising
the light-emitting element according to claim 1.

18-27. (canceled)

28. A nanoparticle dispersion liquid comprising:
a nanoparticle containing a metal compound; and
an organic molecule having a first functional group capable of bonding to the nanoparticle, a second functional group having a hole transport property, and a hydrocarbon group.

29. (canceled)

30. The nanoparticle dispersion liquid according to claim 28, further comprising
a first organic additive having a carbonyl group.

31-32. (canceled)

33. The nanoparticle dispersion liquid according to claim 30, further comprising
a second organic additive greater in viscosity at 20° C. than the first organic additive.

34-41. (canceled)

42. The light-emitting element according to claim 1,
wherein the hydrocarbon group has 1 to 4 carbon atoms.

43. The nanoparticle dispersion liquid according to claim 28, further comprising
a hydrocarbon group having 1 to 4 carbon atoms.
